(19) United States
(12) Patent Application Publication
(10) Pub. No.: US 2008/0227033 A1
(43) Pub. Date: Sep. 18, 2008

(54) Photosensitive Paste Composition, Plasma Display Panel Manufactured Using the Same and Method of Manufacturing the Plasma Display Panel

(76) Inventors: Beom-Wook Lee, Suwon-si (KR); Jong-Seo Choi, Suwon-si (KR); Kwi-Seok Choi, Suwon-si (KR); Myung-Duk Lim, Suwon-si (KR); Hoon-Bae Lee, Suwon-si (KR); Bum-Jin Chang, Suwon-si (KR)

Correspondence Address: CHRISTIE, PARKER & HALE, LLP, PO BOX 7068, PASADENA, CA, 91109-7068, US

(21) Appl. No.: 12/047,246

(22) Filed: Mar. 12, 2008

(30) Foreign Application Priority Data
Mar. 12, 2007 (KR) 10-2007-0024189

(51) Int. Cl. G03F 7/038; G03F 7/00

(52) U.S. Cl. 430/287.1; 430/311

(57) ABSTRACT

Photosensitive paste compositions, plasma display panels (PDP) manufactured using the same, and methods of manufacturing the PDPs are provided. In one embodiment, a photosensitive paste composition includes an inorganic component and an organic component, where the organic component includes a cross-linking agent including a monoacrylate, where the monoacrylate is present in an amount ranging from about 50 to about 100 weight % with respect to a total weight of the cross-linking agent. In another embodiment, a PDP is manufactured using the photosensitive paste composition. In yet another embodiment, a method of manufacturing the PDP is provided. The inventive photosensitive paste compositions can fundamentally prevent film twisting, disconnection or detachment by minimizing stress on the patterned film during sintering, thereby minimizing modifications due to shrinkage.

### CROSS-REFERENCE TO RELATED PATENT APPLICATION

This application claims priority to and the benefit of Korean Patent Application No. 10-2007-0024189, filed on Mar. 12, 2007 in the Korean Intellectual Property Office, the entire content of which is incorporated herein by reference.

### BACKGROUND OF THE INVENTION

1. Field of the Invention

The present invention relates to photosensitive paste compositions, plasma display panels (PDPs) manufactured using the same, and methods of manufacturing the PDPs.

2. Description of the Related Art

Recently, the demand for large, high densification, high precision and high reliability display devices has increased. Accordingly, research has been actively conducted on various techniques for processing fine patterns (such as screen printing methods, ink-jet methods, off-set methods, dispenser methods, photolithography, and the like), and on the formation of micropatterns by developing materials suitable for the technique.

Compared to liquid crystal panels, plasma display panels (PDPs) have quicker response times, and large PDPs can be more easily manufactured. Thus, PDPs are widely used in a variety of fields. Conventionally, the portions of the PDP that require pattern formation include address and bus electrodes, and barrier ribs. At present, electrodes are formed mostly using photolithography. Barrier ribs are mainly formed by sand blasting and etching, and are partially formed using photolithography.

Of the various methods of forming micropatterns described above, interest has arisen in photolithography, which may be suitable for large and high precision PDPs, and which involves a simple preparation process.

Photolithography is performed by printing and drying a photosensitive paste composition to form a film with a desired thickness, irradiating light onto the film using an ultraviolet exposure device equipped with a photomask, selectively removing an unexposed region in a developing process, and then sintering the resulting film.

A conventional photosensitive paste composition includes an inorganic powder and a photosensitive organic component. The component of the inorganic powder is determined by the intended use of the photosensitive paste. For example, when an electrode pattern is formed, powder comprising highly conductive metals such as gold, silver, nickel, copper, aluminum or the like is used. When a pattern of an insulating layer is formed, inorganic oxides such as glass frits, ceramic frits, aluminum oxide, silicon oxide or the like, or mixtures thereof are used. In addition, the photosensitive organic component generally includes a binder, a photo initiator, a cross-linking agent, an additive and a solvent, and each component is designed according to the intended use and required properties.

In photolithography using a photosensitive paste composition, sintering is performed to remove the photosensitive organic component by thermal degradation and to sinter the inorganic powder. However, severe shrinkage occurs during sintering, and the thickness shrinkage ratio is generally higher than the width shrinkage ratio. When the pattern is contracted during sintering, stress occurs, and the pattern becomes twisted or disconnected due to the stress, causing the patterned film to detach from the substrate. In particular, when the pattern shape is a complex structure, such as a matrix or the like, rather than a stripe, such phenomena are more severe.

### SUMMARY OF THE INVENTION

In one embodiment of the present invention, a photosensitive paste composition minimizes the stress on the patterned film during sintering, thereby minimizing modifications due to shrinkage and fundamentally preventing the pattern of the film from twisting, disconnecting or detaching. In another embodiment of the invention, a PDP is manufactured using the photosensitive paste composition. In yet another embodiment, a method of manufacturing the PDP is provided.

According to an embodiment of the present invention, a photosensitive paste composition includes an inorganic component and an organic component, wherein the organic component includes a cross-linking agent including from about 50 to about 100 weight % monoacrylates with respect to a total weight of the cross-linking agent.

According to another embodiment of the present invention, a plasma display panel (PDP) has a pattern prepared using the photosensitive paste composition.

According to yet another embodiment of the present invention, a method of manufacturing a PDP includes applying the photosensitive paste composition on a substrate; drying the photosensitive paste composition; irradiating light onto the dried photosensitive paste composition using an exposure device equipped with a photomask; removing unexposed regions by developing the irradiated composition using an alkali developing solution to form a pattern; removing the organic component of the photosensitive paste composition through plasticizing and sintering; and sintering the inorganic component.

### BRIEF DESCRIPTION OF THE DRAWINGS

The above and other features and advantages of the present invention will become more apparent by reference to the following detailed description when considered in conjunction with the attached drawings in which:

FIG. 1 is a partially exploded perspective view of a plasma display panel (PDP) according to an embodiment of the present invention; and

FIG. 2 is a schematic view of a method of manufacturing a PDP according to an embodiment of the present invention.

### DETAILED DESCRIPTION OF THE INVENTION

In one embodiment of the present invention, a photosensitive paste composition includes an inorganic component and an organic component, where the organic component includes a cross-linking agent including from about 50 to about 100 weight % monoacrylates with respect to the total weight of the cross-linking agent.

During sintering in photolithography, stress is generated on the patterned film, and the patterned film thereby twists, disconnects or detaches. The degree of the stress is believed to be determined by the composition and amount of the cross-linking agent that induces a cross-linking reaction during light exposure. However, when stress is minimized during sintering, phenomena such as twisting, disconnection and detachment can be minimized or prevented. The inventors discovered that when an amount of monoacrylates in the cross-linking agent is large, and an amount of the cross-linking agent in the organic component is small, occurrences of twisting, disconnection and detachment were reduced.

Although the exact reason may not be known, it is believed that the monoacrylates become a thermoplastic resin having a low glass transition temperature by a cross-linking reaction during light exposure, thereby causing fluidity when the temperature is raised during sintering, and minimizing stress. In addition, a product cross-linked by a cross-linking agent has worse fluidity than any other organic substance of the organic component, and thus the smaller the total amount of the cross-linking agent in the organic component, the more fluidity is increased, and the more stress is minimized.

In a photosensitive paste composition according to one embodiment of the present invention, the monoacrylates may be present in an amount ranging from about 50 to about 100 weight % with respect to the total weight of the cross-linking agent. When the monoacrylates are present in an amount less than about 50 weight % with respect to the total weight of the cross-linking agent, the patterned film is twisted, detached or disconnected during sintering.

In addition, the cross-linking agent may be present in the organic component in an amount ranging from about 30 to about 50 weight % with respect to the total amount of the organic component (in the absence of a solvent). In another embodiment, the cross-linking agent may be present in the organic component in an amount ranging from about 30 to about 49.5 weight % with respect to the total amount of the organic component (in the absence of a solvent). According to yet another embodiment, the cross-linking agent may be present in the organic component in an amount ranging from about 34 to about 37 weight % with respect to the total amount of the organic component (in the absence of a solvent). When the cross-linking agent is present in an amount less than about 30 weight % with respect to the total amount of the organic component (in the absence of a solvent), light exposure sensitivity is reduced. When the cross-linking agent is present in an amount greater than about 50 weight % with respect to the total amount of the organic component (in the absence of a solvent), the patterned film is twisted, disconnected or detached during sintering.

Nonlimiting examples of suitable monoacrylates include (meth)acrylic acid, methyl (meth)acrylate, ethyl (meth)acrylate, n-propyl (meth)acrylate, isopropyl (meth)acrylate, n-butyl (meth)acrylate, sec-butyl (meth)acrylate, isobutyl (meth)acrylate, tert-butyl (meth)acrylate, n-pentyl (meth)acrylate, allyl (meth)acrylate, phenyl (meth)acrylate, benzyl (meth)acrylate, butoxyethyl (meth)acrylate, butoxytriethyleneglycol (meth)acrylate, cyclohexyl (meth)acrylate, dicyclopentanyl (meth)acrylate, dicyclopentenyl (meth)acrylate, 2-ethylhexyl (meth)acrylate, glycerol (meth)acrylate, glycidyl (meth)acrylate, isobomyl (meth)acrylate, isodecyl (meth)acrylate, isooctyl (meth)acrylate, lauryl (meth)acrylate, 2-methoxyethyl (meth)acrylate, methoxyethyleneglycol (meth)acrylate, methoxydiethyleneglycol (meth)acrylate, phenoxyethyl (meth)acrylate, stearyl (meth)acrylate, 1-naphthyl (meth)acrylate, 2-naphthyl (meth)acrylate, 2-hydroxyethyl (meth)acrylate, 2-hydroxypropyl (meth)acrylate, aminoethyl (meth)acrylate, and combinations thereof.

In the cross-linking agent, the monoacrylates can be used alone, or can be used in combination with multi-functional acrylates to improve light exposure sensitivity.

Nonlimiting examples of suitable multi-functional acrylates diacrylates (such as 1,6-hexanediol diacrylate, (ethoxylated) 1,6-hexanediol diacrylate, 1,4-butanediol diacrylate, 2-butyl-2-ethyl-1,3-propanediol diacrylate, 1,9-nonanediol diacrylate, tripropyleneglycol diacrylate, dipropyleneglycol diacrylate and tetraethyleneglycol diacrylate), triacrylates (such as trimethylolpropane triacrylate, (ethoxylated) trimethylolpropane triacrylate, (propoxylated) glycerin triacrylate, pentaerithritol triacrylate and (propoxylated) trimethylolpropane-3-triacrylate), tetraacrylates (such as ditrimethylolpropane tetraacrylate, tetramethylolpropane tetraacrylate and pentaerithritol tetraacrylate), pentaacrylates (such as dipentaerithritol pentaacrylate), hexaacrylates (such as dipentaerithritol hexaacrylate), and combinations thereof.

In addition, the organic component of the photosensitive paste composition may further comprise a binder, a photo initiator, a solvent and an additive.

The composition of the binder of the organic component is determined by the developing solution used for development. When the developing solution is pure water, aqueous resins, such as polyvinylalcohols, polyvinylpyrrolidones, polyacrylamides and the like, may be used. When the developing solution is an alkali aqueous solution, an acryl-based resin having a carboxyl group may be used. However, the acryl-based resin having a carboxyl group is generally used since it makes property adjustment according to changes in composition easy.

The acryl-based resin having a carboxyl group makes a paste having an appropriate viscosity, and also can be developed in an alkali aqueous solution. In addition, the acryl-based resin having a carboxyl group may be prepared by copolymerization of a monomer having a carboxyl group and a monomer having an ethylenically unsaturated group to prepare a copolymer.

Nonlimiting examples of suitable monomers having a carboxyl group include acrylic acid, methacrylic acid, fumaric acid, maleic acid, vinylacetic acid, anhydrides thereof, and combinations thereof. Nonlimiting examples of suitable monomers having an ethylenically unsaturated group include methyl (meth)acrylate, ethyl (meth)acrylate, n-propyl (meth)acrylate, isopropyl (meth)acrylate, n-butyl (meth)acrylate, sec-butyl (meth)acrylate, isobutyl (meth)acrylate, tert-butyl (meth)acrylate, n-pentyl (meth)acrylate, allyl (meth)acrylate, phenyl (meth)acrylate, benzyl (meth)acrylate, butoxyethyl (meth)acrylate, butoxytriethyleneglycol (meth)acrylate, cyclohexyl (meth)acrylate, dicyclopentanyl (meth)acrylate, dicyclopentenyl (meth)acrylate, 2-ethylhexyl (meth)acrylate, glycerol (meth)acrylate, glycidyl (meth)acrylate, isobornyl (meth)acrylate, isodecyl (meth)acrylate, isooctyl (meth)acrylate, lauryl (meth)acrylate, 2-methoxyethyl (meth)acrylate, methoxyethyleneglycol (meth)acrylate, methoxydiethyleneglycol (meth)acrylate, phenoxyethyl (meth)acrylate, stearyl (meth)acrylate, 1-naphthyl (meth)acrylate, 2-naphthyl (meth)acrylate, 2-hydroxyethyl (meth)acrylate, 2-hydroxypropyl (meth)acrylate, aminoethyl (meth)acrylate, and combinations thereof.

In addition, the binder may further includes a cross-linkable group which can induce a cross-linking reaction between a monomer having a carboxyl group and an ethylenically unsaturated monomer. Nonlimiting examples of suitable ethylenically unsaturated monomers include glycidyl methacrylate, 3,4-epoxycyclohexylmethyl methacrylate, and 3,4-epoxycyclohexylmethyl acrylate.

In addition, the copolymer can be used alone as the binder. However, for the purpose of enhancing film leveling properties or thixotropic properties, a mixture may be used, where the mixture includes the copolymer and a material selected from cellulose, hydroxymethylcellulose, hydroxyethylcellulose, carboxymethylcellulose, carboxyethylcellulose, carboxyethylmethylcellulose, and combinations thereof.

The binder may be present in an amount ranging from about 100 to about 200 weight % with respect to the total weight of the cross-linking agent. When the binder is present in an amount less than about 100 weight % with respect to the total weight of the cross-linking agent, printing properties deteriorate. When the binder is present in an amount greater than about 200 weight % with respect to the total weight of the cross-linking agent, light exposure sensitivity is reduced, and a pattern having the desired shape is difficult to obtain.

In addition, the copolymer may have a weight average molecular weight ranging from about 5,000 to about 100,000 g/mol and an acid value ranging from about 50 to about 250 mgKOH/g. If the weight average molecular weight of the copolymer is less than about 5,000 g/mol, the paste viscosity is so low that printing properties deteriorate. If the weight average molecular weight of the copolymer is greater than about 100,000 g/mol, the developing speed is too slow or developing is not sufficiently performed. In addition, if the acid value of the copolymer is less than about 50 mgKOH/g, developing properties deteriorate. If the acid value of the copolymer is greater than about 250 mgKOH/g, even exposed regions may be developed.

Nonlimiting examples of suitable photo initiators benzophenone, o-benzoyl benzoic acid methyl ester, 4,4-bis(dimethylamino)benzophenone, 4,4-bis(diethylamino)benzophenone, 2,2-diethoxyacetophenone, 2,2-dimethoxy-2-phenyl-2-phenylacetophenone, 2-methyl-[4-(methylthio)phenyl]-2-morpholinopropan-1-one, 2-benzyl-2-dimethylamino-1-(4-morpholinophenyl)-butan-1-one, bis(2,6-dimethoxybenzoyl)-2,4,4-trimethylpentylphosphineoxide, bis(2,4,6-trimethylbenzoyl)phenylphosphineoxide, and combinations thereof.

The photo initiator may be present in an amount ranging from about 1 to about 50 weight % with respect to the total weight of the cross-linking agent. When the photo initiator is present in an amount less than about 1 weight % with respect to the total weight of the cross-linking agent, light exposure sensitivity is reduced. When the photo initiator is present in an amount greater than about 50 weight % with respect to the total weight of the cross-linking agent, even unexposed regions are not developed.

The solvent in the photosensitive paste composition may be a solvent that dissolves the binder and the photo initiator, that satisfactorily mixes with the cross-linking agent and extra additives, and that has a boiling point of at least about 150° C. When the boiling point of the solvent is less than about 150° C., the possibility of volatilization is high during preparation of the photosensitive paste composition, particularly in a 3-roll mill process, and the solvent is volatilized so quickly during printing that the print state is not good. Nonlimiting examples of suitable solvents included ethyl carbitol, butyl carbitol, ethyl carbitol acetate, butyl carbitol acetate, texanol, terpine oil, dipropyleneglycol methylether, dipropyleneglycol ethylether, dipropyleneglycol monomethylether acetate, γ-butyrolactone, cellosolve acetate, butylcellosolve acetate, tripropylene glycol, and combinations thereof.

The solvent may be present in an amount ranging from about 100 to about 300 weight % with respect to the total weight of the cross-linking agent. When the solvent is present in an amount less than about 100 weight % with respect to the total weight of the cross-linking agent, the viscosity of the paste is so high that printing is not performed. When the solvent is present in an amount greater than about 300 weight % with respect to the total weight of the cross-linking agent, the viscosity of the paste is reduced, and thus printing properties deteriorate.

The photosensitive organic component may further comprise any kind of additive. Nonlimiting examples of additives include sensitizers for improving sensitivity, polymerization inhibitors and antioxidants for improving the storage stability of the photosensitive paste composition, ultraviolet absorbents for improving resolution, antifoaming agents for reducing air bubbles in the composition, dispersants for improving dispersibility, leveling agents for improving smoothness of the membrane during printing, plasticizers for improving printing properties, thixotropic agents for providing thixotropic characteristics, and the like.

According to one embodiment of the present invention, the photosensitive paste composition can be prepared by the following procedure.

First, a solvent is added to a blending tank, and an initiator and additive are added thereto to form a mixture. Then, the mixture is stirred to dissolve the initiator and additive. Next, a binder solution in which a resin is dissolved is added to the blending tank and stirred. A cross-linking agent is then added thereto and the mixture is stirred. When the resulting mixture is completely mixed, the mixed solution is filtered using SUS mesh #600 to prepare an organic component of a photosensitive paste composition.

The prepared organic component is mixed with an inorganic component to prepare a paste. The paste is prepared by adding inorganic powder to a planetary mixer (PLM) and slowly adding the organic component thereto while stirring. When the mixture is completely mixed, the mixture is mechanically mixed by 3-roll milling 3 to 5 times. When the process of 3-roll milling is terminated, the resulting product is filtered using SUS mesh #400, and then degassed using a vacuum pump to prepare a photosensitive paste composition.

According to another embodiment of the present invention, a plasma display panel (PDP) is manufactured using the photosensitive paste composition. The photosensitive paste composition can be used to form a conductive pattern or an insulative pattern of a plasma display panel, for example, to form an electrode pattern on a substrate, or to form a pattern of a barrier rib.

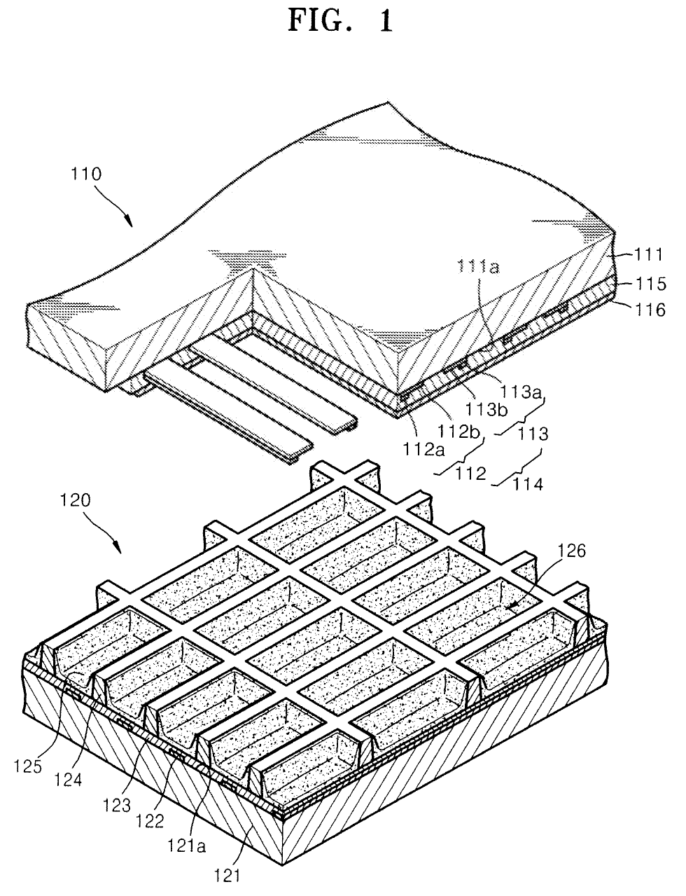

FIG. 1 illustrates a PDP including a pattern prepared using a photosensitive paste composition, according to an embodiment of the present invention. As shown in FIG. 1, the PDP includes a front panel 110 and a rear panel 120. The front panel 110 includes a front substrate 111; sustain electrode pairs 114 formed on a rear surface 111a of the front substrate 111, each sustain electrode pair 114 including a Y electrode 112 and an X electrode 113; a front dielectric layer 115 covering the sustain electrode pairs; and a protective layer 116 covering the front dielectric layer 115. The Y electrode 112 and the X electrode 113 include transparent electrodes 112b and 113b, respectively, made of ITO, etc., and bus electrodes 112a and 113a, respectively, each including a black electrode (not shown) for contrast enhancement and a white electrode (not shown) for imparting conductivity. The bus electrodes 112a and 113a are connected to connection cables disposed on the left and right sides of the PDP.

The rear panel 120 includes a rear substrate 121; address electrodes 122 on a front surface 121a of the rear substrate 121 intersecting the sustain electrode pairs; a rear dielectric layer 123 covering the address electrodes; a barrier rib 124 on the rear dielectric layer 123 to partition discharge cells 126; and a phosphor layer 125 disposed in each discharge cell. The address electrodes 122 are connected to connection cables disposed on upper and lower sides of the PDP.

According to another embodiment of the present invention, a method of manufacturing a PDP includes applying the photosensitive paste composition on a substrate; drying the photosensitive paste composition; irradiating light onto the dried photosensitive paste composition using an exposure device equipped with a photomask; removing an unexposed region by developing the irradiated composition using an alkali developing solution to form a pattern; removing the organic component of the photosensitive paste composition through plasticizing and sintering; and sintering the inorganic component.

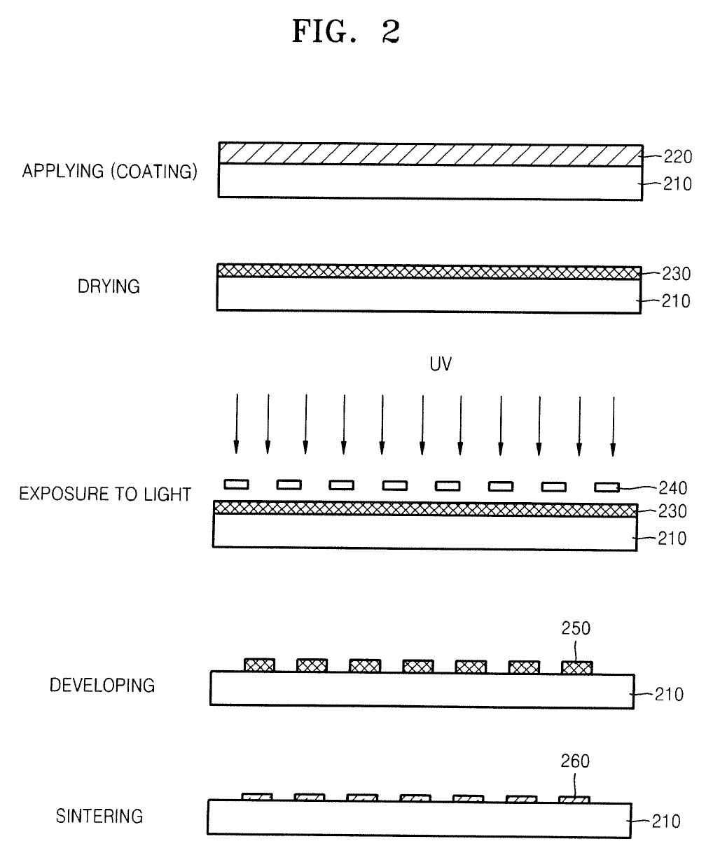

FIG. 2 is a schematic depiction of a method of manufacturing a PDP according to an embodiment of the present invention. Referring to FIG. 2, a method of preparing a barrier rib of a PDP using the photosensitive paste composition is as follows. The photosensitive paste composition 220 is coated on a lower substrate 210 of a PDP (on which address electrodes and a dielectric layer are formed) by screen printing or a table coater, and dried in a dry oven or an IR oven at a temperature ranging from about 8 to about 150° C. for from about 5 to about 60 minutes to remove the majority of solvent from the photosensitive paste composition. As a result, a dried film 230 is formed. Then, light of a predetermined wavelength is irradiated onto the formed paste film using an ultraviolet exposure device in which a photomask 240 is installed.

Thus, a portion of the dried film onto which ultraviolet rays are irradiated becomes insoluble in the developing solution through cross-linking. In the developing process, an appropriate alkaline developer (such as a Na₂CO₃ solution, a KOH solution, a TMAH solution, a monoethanolamine solution, and the like) that is diluted in pure water is used at a developing temperature of about 30° C. to remove unexposed portions of the photosensitive paste. As a result, a patterned film 250 is obtained. The resulting product is sintered in an electric furnace at a temperature ranging from about 500 to about 600° C. for from about 5 to about 60 minutes to remove any remaining organic components and to sinter inorganic powders. Accordingly, a sintered film 260 can be obtained.

The present invention will now be described with reference to the following Examples. The following Examples are presented for illustrative purposes only and are not intended to limit the scope of the invention.

### EXAMPLES

### Example 1

### Preparation of Photosensitive Organic Component A

An organic component of a photosensitive paste compound was prepared by the method of preparing an organic component described above. Photosensitive organic component A was prepared using 15.0 g of poly(methyl methacrylate-co-methacrylic acid) copolymer having a molecular weight of 12,000 g/mol and an acid value of 140 mgKOH/g as the first binder. Component A also included 1.0 g of hydroxypropyl cellulose having an average molecular weight (Mw) of 100,000 g/mol as the second binder. In addition, component A included 0.5 g of 2-methyl-1-[4-(methylthio)phenyl]-2-morpholinopropan-1-one as the first photo initiator. Component A also included 0.5 g of 2,4-diethylthioxantone as the second photo initiator. Additionally, component A included 7.0 g of monoacrylate (such as methoxydiethyleneglycol acrylate) as the first cross-linking agent. Component A further included 3.0 g of triacrylate (such as trimethylolpropane ethoxylated triacrylate) as the second cross-linking agent. Also, component A included 0.5 g of malonic acid as a storage stabilizer. Finally, 12.0 g of texanol was used as a solvent.

### Preparation of Photosensitive Paste A (Conductive Paste)

Photosensitive conductive paste A was prepared using 79.5 volume % of photosensitive organic component A, 19.0 volume % of silver powder (spherical, average particle diameter=1.8 μm), and 1.5 volume % of an inorganic binder (amorphous, SiO₂—B₂O₃—Al₂O₃-based, average particle diameter=1.5 μm).

### Example 2

### Preparation of Photosensitive Organic Component B

Photosensitive organic component B was prepared using 15.0 g of poly(styrene-co-butyl acrylate-co-methacrylic acid) copolymer having a molecular weight of 9,000 g/mol and an acid value of 170 mgKOH/g as a binder. Component B also included 3.0 g of 2-benzyl-2-dimethylamino-1-(4-morpholinophenyl)-butan-1-one as a photo initiator, 10.0 g of monoacrylate (such as phenoxyethyl acrylate) as a cross-linking agent, 1.0 g of benzotriazole as a storage stabilizer, and 18.0 g of γ-butyrolactone as a solvent.

### Preparation of Photosensitive Paste B (Insulative Paste)

Photosensitive insulative paste B was prepared using 50 volume % of photosensitive organic component B, 45 volume % of a glass frit (amorphous, SiO₂—B₂O₃—Al₂O₃-based, average particle diameter=3.2 μm), and 5 volume % of a filler having a high melting point (amorphous, SiO₂—B₂O₃—CaO-based, average particle diameter=3.4 μm).

### Example 3

### Preparation of Photosensitive Organic Component C

Photosensitive organic component C was prepared using 15.0 g of poly(styrene-co-butyl acrylate-co-methacrylic acid) copolymer having a molecular weight of 9,000 g/mol and an acid value of 170 mgKOH/g as a binder. Component C also included 0.5 g of bis(2,4,6-trimethylbenzoyl)phenylphosphineoxide as a photo initiator, 7.0 g of monoacrylate (such as phenoxyethyl acrylate) as the first cross-linking agent, 3.0 g of bisphenol A-diacrylate as the second cross-linking agent, 1.0 g of benzotriazole as a storage stabilizer, and 18.0 g of γ-butyrolactone as a solvent.

### Preparation of Photosensitive Paste C (Insulative Paste)

Photosensitive insulative paste C was prepared using 50 volume % of photosensitive organic component C, 45 volume % of a glass frit (amorphous, SiO₂—B₂O₃—Al₂O₃-based, average particle diameter=3.2 μm), and 5 volume % of a filler having a high melting point (amorphous, SiO₂—B₂O₃—CaO-based, average particle diameter=3.4 μm).

### Comparative Example 1

### Preparation of Photosensitive Organic Component D

Photosensitive organic component D was prepared using 15.0 g of poly(methyl methacrylate-co-methacrylic acid) copolymer having a molecular weight of 12,000 g/mol and an acid value of 140 mgKOH/g as the first binder. Component D also included 1.0 g of hydroxypropyl cellulose having an average molecular weight (Mw) of 100,000 g/mol as the second binder. In addition, component D included 0.5 g of 2-methyl-1-[4-(methylthio)phenyl]-2-morpholinopropan-1-one as the first photo initiator. Component D further included 0.5 g of 2,4-diethylthioxantone as the second photo initiator. Additionally, component D included 10.0 g of triacrylate (such as trimethylolpropane ethoxylated triacrylate) as a cross-linking agent, 0.5 g of malonic acid as a storage stabilizer, and 12.0 g of texanol as a solvent.

### Preparation of Photosensitive Paste D (Conductive Paste)

Photosensitive conductive paste D was prepared using 79.5 volume % of photosensitive organic component D, 19.0 volume % of silver powder (spherical, average particle diameter=1.8 μm), and 1.5 volume % of an inorganic binder (amorphous, SiO₂—B₂O₃—Al₂O₃-based, average particle diameter=1.5 μm).

### Comparative Example 2

### Preparation of Photosensitive Organic Component E

Photosensitive organic component E was prepared using 15.0 g of poly(styrene-co-butyl acrylate-co-methacrylic acid) copolymer having a molecular weight of 9,000 g/mol and an acid value of 170 mgKOH/g as a binder. Component E also included 3.0 g of 2-benzyl-2-dimethylamino-1-(4-morpholinophenyl)-butan-1-one as a photo initiator. In addition, component E included 10.0 g of a triacrylate (such as trimethylolpropane ethoxylated triacrylate) as a first cross-linking agent. Component E further included 3.0 g of bisphenol A-diacrylate as a second cross-linking agent. Additionally, component E included 1.0 g of benzotriazole as a storage stabilizer, and 18.0 g of γ-butyrolactone as a solvent.

### Preparation of Photosensitive Paste E (Insulative Paste)

Photosensitive insulative paste E was prepared using 50 volume % of photosensitive organic component E, 45 volume % of a glass frit (amorphous, SiO₂—B₂O₃—Al₂O₃-based, average particle diameter=3.2 μm), and 5 volume % of a filler having a high melting point (amorphous, SiO₂—B₂O₃—CaO-based, average particle diameter=3.4 μm).

### Comparative Example 3

### Preparation of Photosensitive Organic Component F

Photosensitive organic component F was prepared using 15.0 g of poly(styrene-co-butyl acrylate-co-methacrylic acid) copolymer having a molecular weight of 9,000 g/mol and an acid value of 170 mgKOH/g as a binder. Component F also included 0.5 g of bis(2,4,6-trimethylbenzoyl)phenylphosphineoxide as a photo initiator. In addition, component F included 3.0 g of a monoacrylate (such as phenoxyethyl acrylate) as a first cross-linking agent. Component F further included 7.0 g of bisphenol A-diacrylate as a second cross-linking agent. Additionally, component F included 1.0 g of benzotriazole as a storage stabilizer and 18.0 g of γ-butyrolactone as a solvent.

### Preparation of Photosensitive Paste F (Insulative Paste)

Photosensitive insulative paste F was prepared using 50 volume % of photosensitive organic component F, 45 volume % of a glass frit (amorphous, SiO₂—B₂O₃—Al₂O₃-based, average particle diameter=3.2 μm), and 5 volume % of a filler having a high melting point (amorphous, SiO₂—B₂O₃—CaO-based, average particle diameter=3.4 μm).

### Comparative Example 4

### Preparation of Photosensitive Organic Component G

Photosensitive organic component G was prepared using 10.0 g of poly(styrene-co-butyl acrylate-co-methacrylic acid) copolymer having a molecular weight of 9,000 g/mol and an acid value of 170 mgKOH/g as a binder. Component G also included 0.5 g of bis(2,4,6-trimethylbenzoyl)phenylphosphineoxide as a photo initiator. In addition, component G included 10.0 g of a monoacrylate (such as phenoxyethyl acrylate) as a first cross-linking agent. Component G further included 5.0 g of bisphenol A-diacrylate as a second cross-linking agent. Additionally, component G included 1.0 g of benzotriazole as a storage stabilizer, and 18.0 g of γ-butyrolactone as a solvent.

### Preparation of Photosensitive Paste G (Insulative Paste)

Photosensitive insulative paste G was prepared using 50 volume % of photosensitive organic component G, 45 volume % of a glass frit (amorphous, SiO₂—B₂O₃—Al₂O₃-based, average particle diameter=3.2 μm), and 5 volume % of a filler having a high melting point (amorphous, SiO₂—B₂O₃—CaO-based, average particle diameter=3.4 μm).

### Evaluation of Photosensitive Pastes

### Evaluation Method

Properties of the photosensitive paste compositions of Examples 1 through 3 and Comparative Examples 1 through 4 were evaluated by the following method.

First, the photosensitive conductive pastes A and D (Example 1 and Comparative Example 1) were each printed on a 6″ glass substrate using a screen printer, and then dried in a dry oven at 100° C. for 15 minutes. Subsequently, 400-700 mJ/cm² of light was irradiated using a high voltage mercury lamp ultraviolet exposure device equipped with a photomask. The light-irradiated glass substrate was developed by spraying it with 0.4% by weight of an aqueous NaCO₃ solution at 30° C. at a nozzle pressure of 1.5 kgf/cm² for 40 seconds. The glass was then rinsed by spraying it with pure water at room temperature at a nozzle pressure of 1.5 kgf/cm² for seconds. Subsequently, the developed glass substrate was dried using an air knife and then placed into an electric furnace and sintered at 560° C. for 15 minutes to form a sintered film. Then, the properties of the sintered patterned film were evaluated using an optical microscope.

Properties of the photosensitive insulative pastes B, C and E through G (Examples 2 and 3 and Comparative Examples 2 through 4) were evaluated by the following procedure. The photosensitive insulative pastes were each coated on a 6″ glass substrate using a coater, and then dried in a dry oven at 100° C. for 30 minutes. Subsequently, 500-1,000 mJ/cm² of light was irradiated using a high voltage mercury lamp ultraviolet exposure device equipped with a photomask. The light-irradiated glass substrate was developed by spraying it with 0.4% by weight of an aqueous NaCO₃ solution at 30° C. at a nozzle pressure of 1.5 kgf/cm² for 120 seconds. The glass was then rinsed by spraying it with pure water at room temperature at a nozzle pressure of 1.5 kgf/cm² for 30 seconds. Subsequently, the developed glass substrate was dried using an air knife and then placed into an electric furnace and sintered at 570° C. for 10 minutes to form a sintered film. Then, the properties of the sintered patterned film were evaluated using an optical microscope.

### Evaluation Results

### Evaluation Results of the Photosensitive Conductive Pastes

Evaluation results of the photosensitive conductive pastes are shown in Table 1 below.

From the results shown in Table 1 below, it can be seen that paste A had a greater thickness shrinkage ratio and smaller width shrinkage ratio than those of paste D. Paste A is believed to have a higher thickness shrinkage ratio and smaller width shrinkage ratio because the substance produced by the cross-linking reaction in paste A has thermoplastic properties, and thus becomes soft and fluid when the temperature is raised. As a result, paste A exhibited much better results in terms of compactness of the sintered film, twisting or detachment of the film, and the like.

TABLE 1

| | paste A | paste D |
|---|---|---|
| Dried film thickness | 12.2 μm | 12.0 μm |
| Sintered film thickness | 6.1 μm | 6.8 μm |
| Pattern width before | 150 μm | 150 μm |
| sintering | | |
| Pattern width after | 142 μm | 138 μm |
| sintering | | |
| Sintered film compactness | Excellent | Average |
| Degree of twist | None | Partially generated |
| Disconnection | None | None |
| Detachment | None | Partially generated |

### Evaluation Results of the Photosensitive Insulative Pastes

Evaluation results of the photosensitive insulative pastes are shown in Table 2 below.

From the results shown in Table 2 below, it can be seen that pastes B and C had greater thickness shrinkage ratios, but smaller width shrinkage ratios compared with pastes E, F and G during sintering. This is due to the same reasons discussed above with respect to photosensitive conductive paste A. Pastes B and C also exhibited good sintered film properties. On the other hand, pastes E, F and G had poor twisting, disconnection and detachment properties and only average film compactness. Paste E included a cross-linking agent that included triacrylates and no monoacrylates, and it exhibited the poorest sintered film properties. Paste F and paste G exhibited poor film properties during sintering. Paste F included a cross-linking agent including 50 weight % or less of monoacrylates. Although paste G included a cross-linking agent including greater than 50 weight % of monoacrylates, the total amount of the cross-linking agent was greater than 50 weight % with respect to the total weight of the organic component (excluding solvent).

TABLE 2

| | paste B | paste C | paste E | paste F | paste G |
|---|---|---|---|---|---|
| Dried film | 62 μm | 60 μm | 60 μm | 62 μm | 63 μm |
| thickness | | | | | |
| Sintered film | 30 μm | 29 μm | 38 μm | 34 μm | 35 μm |
| thickness | | | | | |
| Pattern width | 50 μm | 51 μm | 50 μm | 51 μm | 50 μm |
| before sintering | | | | | |
| Pattern width | 46 μm | 48 μm | 41 μm | 44 μm | 43 μm |
| after sintering | | | | | |
| Sintered film | Excellent | Excellent | Average | Average | Average |
| compactness | | | | | |
| Degree of twist | None | None | Bad | Partially | Partially |
| | | | | generated | generated |
| Disconnection | None | None | Bad | Partially | Partially |
| | | | | generated | generated |
| Detachment | None | None | Bad | Partially | Partially |
| | | | | generated | generated |

According to embodiments of the present invention, photosensitive paste compositions fundamentally prevent twisting, disconnection or detachment of a patterned film by minimizing stress on the patterned film during sintering, thereby minimizing modifications due to shrinkage. According to another embodiment of the present invention, a PDP is manufactured using the photosensitive paste composition. In yet another embodiment, a method of manufacturing the PDP is provided.

While the present invention has been illustrated and described with reference to certain exemplary embodiments, it will be understood by those of ordinary skill in the art that various changes and modifications may be made to the described embodiments without departing from the spirit and scope of the present invention as defined by the following claims.

What is claimed is:

1. A photosensitive paste composition comprising an inorganic component and an organic component, wherein the organic component comprises a cross-linking agent comprising a monoacrylate, the monoacrylate being present in the cross-linking agent in an amount ranging from about 50 to about 100 weight % with respect to a total weight of the cross-linking agent.

2. The photosensitive paste composition of claim 1, wherein the cross-linking agent is present in the organic component in an amount ranging from about 30 to about 50 weight % with respect to a total weight of the organic component absent a solvent.

3. The photosensitive paste composition of claim 1, wherein the monoacrylate is selected from the group consisting of (meth)acrylic acid, methyl (meth)acrylate, ethyl (meth)acrylate, n-propyl (meth)acrylate, isopropyl (meth)acrylate, n-butyl (meth)acrylate, sec-butyl (meth)acrylate, isobutyl (meth)acrylate, tert-butyl (meth)acrylate, n-pentyl (meth)acrylate, allyl (meth)acrylate, phenyl (meth)acrylate, benzyl (meth)acrylate, butoxyethyl (meth)acrylate, butoxytriethyleneglycol (meth)acrylate, cyclohexyl (meth)acrylate, dicyclopentanyl (meth)acrylate, dicyclopentenyl (meth)acrylate, 2-ethylhexyl (meth)acrylate, glycerol (meth)acrylate, glycidyl (meth)acrylate, isobornyl (meth)acrylate, isodecyl (meth)acrylate, isooctyl (meth)acrylate, lauryl (meth)acrylate, 2-methoxyethyl (meth)acrylate, methoxyethyleneglycol (meth)acrylate, methoxydiethyleneglycol (meth)acrylate, phenoxyethyl (meth)acrylate, stearyl (meth)acrylate, 1-naphthyl (meth)acrylate, 2-naphthyl (meth)acrylate, 2-hydroxyethyl (meth)acrylate, 2-hydroxypropyl (meth)acrylate, aminoethyl (meth)acrylate, and combinations thereof.

4. The photosensitive paste composition of claim 1, wherein the cross-linking agent further comprises a multi-functional acrylate.

5. The photosensitive paste composition of claim 4, wherein the multi-functional acrylate is selected from the group consisting of:
diacrylates selected from the group consisting of 1,6-hexanediol diacrylate, (ethoxylated) 1,6-hexanediol diacrylate, 1,4-butanediol diacrylate, 2-butyl-2-ethyl-1,3-propanediol diacrylate, 1,9-nonanediol diacrylate, tripropyleneglycol diacrylate, dipropyleneglycol diacrylate, tetraethyleneglycol diacrylate, and combinations thereof;
triacrylates selected from the group consisting of trimethylolpropane triacrylate, (ethoxylated) trimethylolpropane triacrylate, (propoxylated) glycerin triacrylate, pentaerithritol triacrylate, (propoxylated) trimethylolpropane-3-triacrylate, and combinations thereof;
tetraacrylates selected from the group consisting of ditrimethylolpropane tetraacrylate, tetramethylolpropane tetraacrylate, pentaerithritol tetraacrylate, and combinations thereof;
dipentaerithritol pentaacrylate;
dipentaerithritol hexaacrylate; and
mixtures thereof.

6. The photosensitive paste composition of claim 1, wherein the organic component further comprises a binder, a photo initiator, a solvent and an additive.

7. The photosensitive paste composition of claim 6, wherein the binder is present in the organic component in an amount ranging from about 100 to about 200 weight % with respect to a total weight of the cross-linking agent, wherein the photoinitiator is present in the organic component in an amount ranging from about 1 to about 50 weight % with respect to a total weight of the cross-linking agent, and wherein the solvent is present in an amount ranging from about 100 to about 300 weight % with respect to a total weight of the cross-linking agent.

8. The photosensitive paste composition of claim 1, wherein the binder is a copolymer of a monomer having a carboxyl group and at least one ethylenically unsaturated monomer.

9. The photosensitive paste composition of claim 8, wherein:
the monomer having a carboxyl group is selected from the group consisting of acrylic acid, methacrylic acid, fumaric acid, maleic acid, vinylacetic acid, anhydrides thereof, and combinations thereof, and
the monomer having an ethylenically unsaturated group is selected from the group consisting of (meth)acrylic acid, methyl (meth)acrylate, ethyl (meth)acrylate, n-propyl (meth)acrylate, isopropyl (meth)acrylate, n-butyl (meth)acrylate, sec-butyl (meth)acrylate, isobutyl (meth)acrylate, tert-butyl (meth)acrylate, n-pentyl (meth)acrylate, allyl (meth)acrylate, phenyl (meth)acrylate, benzyl (meth)acrylate, butoxyethyl (meth)acrylate, butoxytriethyleneglycol (meth)acrylate, cyclohexyl (meth)acrylate, dicyclopentanyl (meth)acrylate, dicyclopentenyl (meth)acrylate, 2-ethylhexyl (meth)acrylate, glycerol (meth)acrylate, glycidyl (meth)acrylate, isobornyl (meth)acrylate, isodecyl (meth)acrylate, isooctyl (meth)acrylate, lauryl (meth)acrylate, 2-methoxyethyl (meth)acrylate, methoxyethyleneglycol (meth)acrylate, methoxydiethyleneglycol (meth)acrylate, phenoxyethyi (meth)acrylate, stearyl (meth)acrylate, 1-naphthyl (meth)acrylate, 2-naphthyl (meth)acrylate, 2-hydroxyethyl (meth)acrylate, 2-hydroxypropyl (meth)acrylate, aminoethyl (meth)acrylate, and combinations thereof.

10. The photosensitive paste composition of claim 6, wherein the photo initiator is selected from the group consisting of benzophenone, o-benzoyl benzoic acid methyl ester, 4,4-bis(dimethylamino)benzophenone, 4,4-bis(diethylamino)benzophenone, 2,2-diethoxyacetophenone, 2,2-dimethoxy-2-phenyl-2-phenylacetophenone, 2-methyl-[4-(methylthio)phenyl]-2-morpholinopropan-1-one, 2-benzyl-2-dimethylamino-1-(4-morpholinophenyl)-butan-1-one, bis(2,6-dimethoxybenzoyl)-2,4,4-trimethylpentylphosphineoxide, bis(2,4,6-trimethylbenzoyl)phenylphosphineoxide, and combinations thereof.

11. The photosensitive paste composition of claim 6, wherein the solvent is selected from the group consisting of ethyl carbitol, butyl carbitol, ethyl carbitol acetate, butyl carbitol acetate, texanol, terpine oil, dipropyleneglycol methylether, dipropyleneglycol ethylether, dipropyleneglycol monomethylether acetate, γ-butyrolactone, cellosolve acetate, butylcellosolve acetate, tripropylene glycol, and combinations thereof.

12. The photosensitive paste composition of claim 8, wherein the copolymer has a cross-linkable group comprising a reaction product of the carboxyl group of the monomer having a carboxyl group and the ethylenically unsaturated monomer, wherein the ethylenically unsaturated monomer is selected from the group consisting of glycidylmethacrylate, 3,4-epoxycyclohexylmethylmethacrylate, and 3,4-epoxycyclohexylmethylacrylate.

13. The photosensitive paste composition of claim 8, wherein the copolymer has a weight average molecular weight ranging from about 5,000 to about 100,000 g/mol, and an acid value ranging from about 50 to about 250 mgKOH/g.

14. The photosensitive paste composition of claim 6, wherein the additive is selected from the group consisting of sensitizers, polymerization inhibitors, antioxidants, ultraviolet absorbents, antifoaming agents, dispersants, leveling agents, plasticizers, thixotropic agents, and combinations thereof.

15. The photosensitive paste composition of claim 6, wherein the binder further comprises a material selected from the group consisting of cellulose, hydroxymethylcellulose, hydroxyethylcellulose, carboxymethylcellulose, carboxyethylcellulose, carboxyethylmethylcellulose, and combinations thereof.

16. A photosensitive paste composition comprising an inorganic component and an organic component, wherein the organic component comprises a cross-linking agent comprising a monoacrylate, the monoacrylate being present in the cross-linking agent in an amount ranging from about 50 to about 100 weight % with respect to a total weight of the cross-linking agent, and wherein the cross-linking agent is present in the organic component in an amount ranging from about 30 to about 50 weight % with respect to a total weight of the organic component absent a solvent.

17. The photosensitive paste composition of claim 16, wherein the cross-linking agent further comprises a multi-functional acrylate.

18. The photosensitive paste composition of claim 16, wherein the organic component further comprises a binder, a photo initiator, a solvent and an additive.

19. A plasma display panel (PDP) comprising a pattern formed by a photosensitive paste composition according to claim 1.

20. The PDP of claim 19, wherein the pattern is selected from the group consisting of conductive patterns and insulative patterns.

21. A method of manufacturing a PDP, comprising:
applying the photosensitive paste composition according to claim 1 on a substrate;
drying the photosensitive paste composition;
irradiating light onto the photosensitive paste composition using an exposure device having a photomask;
removing unexposed regions of the photosensitive paste composition by developing the photosensitive paste composition with an alkali developing solution to form a pattern;
removing an organic component of the photosensitive paste composition by plasticizing and sintering; and
sintering an inorganic component of the photosensitive paste composition.

22. The method of claim 21, wherein the pattern is selected from the group consisting of conductive patterns and insulative patterns.
